(19) United States
(12) Patent Application Publication
(10) Pub. No.: US 2011/0232753 A1
(43) Pub. Date: Sep. 29, 2011

(54) METHODS OF FORMING A THIN-FILM SOLAR ENERGY DEVICE

(75) Inventors: Shuran Sheng, Cupertino, CA (US); Yong Kee Chae, San Ramon, CA (US)

(73) Assignee: APPLIED MATERIALS, INC., Santa Clara, CA (US)

(21) Appl. No.: 12/729,777

(22) Filed: Mar. 23, 2010

(51) Int. Cl. H01L 31/0368; H01L 31/18

(52) U.S. Cl. 136/258; 438/97; 257/E31.043

(57) ABSTRACT

A method and apparatus for making solar cell active layers is provided. A doped microcrystalline semiconductor layer is formed with a bandgap-enhancing alloy material at low hydrogen flow rates. Deposition conditions are established at a low flowrate of the semiconductor source and ramped to a high flowrate as a first sublayer is deposited. The bandgap-enhancing alloy material is added to the reaction mixture to deposit a second sublayer. The bandgap-enhancing alloy material may optionally be stopped to deposit a third sublayer.

### FIELD

Embodiments described herein generally relate to solar cells and methods and apparatuses for forming the same. More particularly, the embodiments relate to layer structures in thin-film and crystalline solar cells.

### BACKGROUND

Crystalline silicon solar cells and thin film solar cells are two types of solar cells. Crystalline silicon solar cells typically use either mono-crystalline substrates (i.e., single-crystal substrates of pure silicon) or multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates.

To expand the economic uses of solar cells, efficiency must be improved. Solar cell efficiency relates to the proportion of incident radiation converted into useful electricity. To be useful for more applications, solar cell efficiency must be improved beyond the current best performance of approximately 15%. With energy costs rising, there is a need for improved thin film solar cells and methods and apparatuses for forming the same in a factory environment.

### SUMMARY

Embodiments described herein provide a method of forming a thin-film solar cell by positioning a substrate in a processing chamber by exposing the substrate to a processing environment at a high crystallinity deposition condition in the processing chamber, ramping the processing environment to a low crystallinity deposition condition, depositing a first doped semiconductor layer on the substrate while ramping the processing environment, and depositing a second doped semiconductor layer on the substrate while maintaining the low crystallinity deposition condition.

Other embodiments provide a method of forming a solar cell by forming a first photojunction layer adjacent to a first conductor layer on a substrate, the first photojunction layer comprising a first n-type doped semiconductor layer, a first intrinsic semiconductor layer, and a first p-type doped semiconductor layer, wherein the first n-type doped semiconductor layer is formed by exposing the substrate to a first gas mixture comprising a silicon containing gas at a first flow rate, ramping the flow rate of the silicon containing gas to a second flow rate, and depositing the first n-type doped semiconductor layer while ramping the flow rate of the silicon containing gas from the first flow rate to the second flow rate.

Other embodiments provide a solar cell device with a microcrystalline doped semiconductor layer in contact with a first microcrystalline doped semiconductor alloy layer.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment.

FIG. 2 is a schematic stack diagram of a solar cell device according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

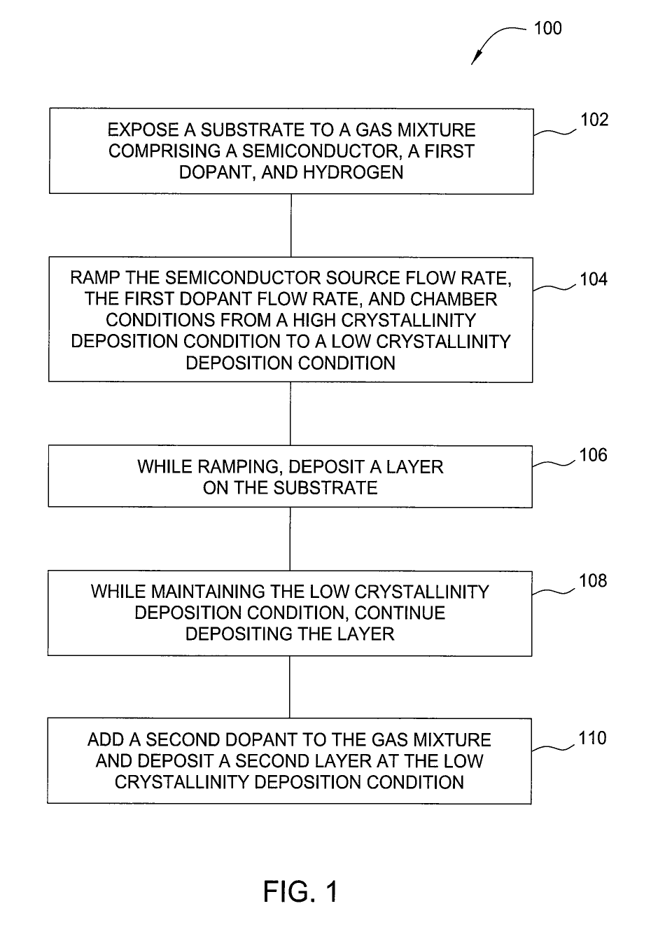

FIG. 1 is a flow diagram summarizing a method 100 according to one embodiment. The method 100 of FIG. 1 may be used in forming one or more doped semiconductor layers of a thin-film solar cell. Thin-film solar cells generally comprise one or more doped semiconductor layers that form photovoltaic cells. P-type and n-type doped semiconductor layers are generally formed with one or more intrinsic semiconductor layers between them. The intrinsic semiconductor layer collects light to generate free electrons and holes, which migrate toward the p-type and n-type doped semiconductor layers, respectively. The layers may be formed with different morphologies to facilitate capturing different portions of the spectrum. Most layers in the device will be microcrystalline, but a few amorphous layers are usually included to capture lower wavelengths of light. The method 100 of FIG. 1 is generally used in forming microcrystalline layers for a thin-film solar cell device.

At 102 a substrate is exposed to a gas mixture comprising a semiconductor, a first dopant, and hydrogen. The substrate used may be any structural substrate suitable for solar cell applications. The substrate may be transparent if it is to admit light into the device, or opaque or reflective if it is to form the back surface of the device. Various types of glasses, such as borosilicate glass (BSG), phosphosilicate glass (PSG), borophosphosilicate glass (BPSG), sodalite glass, and the like, are commonly used. Polymers such as plastics and metal substrates may also be used. Semiconductor substrates such as silicon or germanium may also be used.

The substrate comprises a conductor layer formed over the structural substrate. The conductor layer may comprise a transparent dielectric, such as a metal oxide, doped with a conductive material. Oxides of zinc (Zn), tin (Sb), indium (In), aluminum (Al), titanium (Ti), cadmium (Cd), gallium (Ga), or silver (Ag) may be doped with any of those metals to form a transparent conductive oxide layer suitable for use as a conductor. In some embodiments, zinc oxide (ZnO) is doped with aluminum (Al), indium (In), tin (Sb), gallium (Ga), boron (B), or silver (Ag). Indium tin oxide or cadmium stannate may also be used. In some embodiments, a metal doped silicate layer may also be used as a conductor. To improve light absorption by reducing light reflection, the substrate and/or one or more of thin films formed thereover, such as the conductor layer described above, may be textured by wet, plasma, ion, or mechanical processes, or combinations thereof.

In other embodiments, the substrate may comprise a plurality of layers of a solar cell. For example, in one embodiment, the method 100 may be used to form a p-type doped semiconductor layer, which may be an alloy layer, over an intrinsic semiconductor layer of a photovoltaic junction. In another embodiment, the method 100 may be used to form an n-type doped semiconductor layer, which may be an alloy layer, over a p-type doped semiconductor layer in a tandem junction thin-film solar cell. In another embodiment, the method 100 may be used to form an n-type doped semiconductor layer, which may be an alloy layer, over a buffer layer. Any microcrystalline semiconductor layer of a thin-film solar cell may be formed according to the method 100 of FIG. 1.

The substrate is positioned in a processing chamber for exposure to the gas mixture. The processing chamber may be a CVD chamber, which may utilize plasma enhancement (i.e. a PECVD chamber). Suitable chambers include the PECVD 5.7™ chamber manufactured by Applied Materials, Inc., located in Santa Clara, Calif., and implemented in the SUNFAB® solar manufacturing facility, also available from Applied Materials. Plasma deposition chambers manufactured by others may also be used to perform the methods described herein.

The semiconductor component of the gas mixture may be a silicon containing material. In many instances, the silicon source compound is silane, but other compounds, such as substituted silanes, oligo- or poly-silanes, and cyclic silanes may be used as well. Some suitable silicon source compounds are silane (SiH₄), disilane (Si₂H₆), silicon tetrafluoride (SiF₄), silicon tetrachloride (SiCl₄), and dichlorosilane (SiH₂Cl₂). In general it is preferred that silicon source compounds be readily vaporized without decomposing for delivery to the process chamber. Semiconductor materials besides silicon, such as germanium, may be delivered using relatively low-boiling compounds such as germane (GeH₄) and derivatives thereof. A mixture of any of the above may also be used.

The first dopant is an n-type or p-type electrical activator dopant, such as phosphorus, boron, arsenic, aluminum, or antimony, or a bandgap-enhancing dopant such as carbon. P-type dopants are generally group III elements, electron deficient relative to the group IV semiconductors, while n-type dopants are generally group V elements, electron rich relative to the semiconductors. Boron is frequently used as a p-type dopant and phosphorus as an n-type dopant. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is the most common phosphorus compound. Phosphorus and boron are generally combined with a carrier gas such as hydrogen, helium, or argon.

Carbon may be added to the film using a carbon source such as methane (CH₄) or other lower hydrocarbons to the gas mixture. In general, C₁-C₄ hydrocarbons may be used as carbon sources. Alternately, organosilicon compounds known to the art, such as organosilanes, organosiloxanes, organosilanols, and the like may serve as both silicon and carbon sources.

The gas mixture is initially provided at a composition that fosters formation of a high crystallinity doped semiconductor layer. Hydrogen content of the gas mixture controls the initial crystallinity of the deposited layer. In one example, the high crystallinity deposition condition comprises a volumetric flow rate of hydrogen and a first volumetric flow rate of the silicon source, in a ratio of hydrogen to silicon source between about 50:1 and about 5,000:1 by volume, such as between about 100:1 and about 1,000:1, for example about 600:1. Normalized to chamber size, the hydrogen is provided at a flow rate between about 50 sccm/L and about 2,000 sccm/L, such as between about 100 sccm/L and about 500 sccm/L, for example about 350 sccm/L. The silicon source is provided at a flow rate between about 0.1 sccm/L and about 2.0 sccm/L, for example between about 0.3 sccm/L and about 1.0 sccm/L, for example about 0.58 sccm/L.

The gas mixture may comprise one or more dopant sources. A p-type or n-type doped semiconductor alloy layer may be formed by including a p-type or n-type dopant along with an alloy material or dopant. Carbon is a suitable alloy material for increasing the bandgap and decreasing the refractive index of a microcrystalline semiconductor layer. If a p-type or n-type doped semiconductor alloy layer is to be formed, the dopant source will include a p-type or n-type dopant and an alloy material, such as carbon. The dopant source is provided at a volumetric flow rate such that the ratio of the silicon source to the p-type or n-type dopant source is between about 20:1 and about 4,000:1, such as between about 50:1 and about 1,000:1, for example about 200:1. Thus, the p-type or n-type dopant source is provided at a flow rate between about 0.0005 sccm/L and about 0.005 sccm/L, such as about 0.003 sccm/L. If the dopant is provided with a carrier gas, the flow of the dopant/carrier mixture is consistent with the above ratios for the high crystallinity deposition condition. A carbon source may be provided at a flow rate ratio to the silicon source of between about 0 and about 3:1 by volume, for example between about 0.3:1 and about 1:1, such as about 0.5:1.

The high crystallinity deposition condition further comprises a plasma power level and chamber pressure that fosters deposition of a high crystallinity doped semiconductor layer. The plasma power level, generated by a 13.56 MHz frequency RF driven plasma generator that may be inductive or capacitative, is between about 10 mW/cm² and about 5,000 mW/cm², such as between about 50 mW/cm² and about 1,000 mW/cm², for example about 200 mW/cm². The chamber pressure is between about 0.1 Torr and about 10 Torr, for example between about 1 Torr and about 5 Torr, such as about 2 Torr.

At 104, the processing environment is ramped from the high crystallinity deposition condition to a low crystallinity deposition condition. The hydrogen flow rate may be held constant during the ramping, such that the flow rates of the other components of the gas mixture change with respect to the hydrogen flow rate. The silicon source, for example, is ramped from the first flow rate to a second flow rate. The low crystallinity deposition condition generally comprises a lower ratio of hydrogen to the silicon source in the gas mixture, with the second flow rate of the silicon source higher than the first flow rate, because hydrogen concentration affects the crystallinity of the deposited layer. Because a high crystallinity layer was deposited first, however, the material subsequently deposited at a low crystallinity deposition condition will deposit according to the structure of the high crystallinity material. Thus, a high crystallinity layer may be formed using lower flow rates of hydrogen than would otherwise be needed, resulting in lighter equipment loading.

The ratio of hydrogen to the silicon source at the low crystallinity deposition condition is between about 100:1 and about 700:1. The ratios of the one or more dopant or alloy material sources to the silicon source are generally the same at the low crystallinity deposition condition as at the high crystallinity condition. The power level at the low crystallinity condition is between about 100 mW/cm² and about 5,000 mW/cm², for example between about 200 mW/cm² and about 1,000 mW/cm², such as about 600 mW/cm². The pressure in the process chamber at the low crystallinity condition is between about 5 Torr and about 15 Torr, such as about 10 Torr.

Specific process parameters may be ramped concurrently or sequentially, or any combination thereof. Times for starting ramping and for reaching end points for the various ramped parameters may be the same or different. For example, gas flow rates may be ramped to an end point and then RF power ramped to its end point, or vice versa.

At 106, a layer is deposited on the substrate during ramping. The layer is a semiconductor layer having one or more dopants for affecting electrical activity. The layer is generally microcrystalline although deposited at gas flow conditions that would ordinarily produce low or no crystallinity. The layer may have a graded composition in some embodiments, due to ramping of gas components at different rates or times, or due to ramping of gas flows at different rates and times from power levels, or any combination thereof. In one embodiment, the layer is a carbon containing silicon layer doped with a p-type or n-type dopant, and the carbon content of the layer increases with distance from the conductor layer. In another embodiment, concentration of the n-type dopant or the p-type dopant may be graded.

Ramping generally takes place for a time period selected to deposit a layer of a desired thickness during the ramping. In one embodiment, the duration of the ramping is between about 30 seconds and about 120 seconds, such as about 60 seconds.

Semiconductor alloy layers are generally formed by adding an alloy component to a semiconductor matrix in a concentration range that gives a desired bandgap, conductivity, and/or refractive index. In one example, a carbon containing silicon material serves as a semiconductor alloy layer in a thin-film solar cell. The carbon increases the bandgap of the silicon and reduces its refractive index, to reduce absorption of light by the n and p layers of the solar cell. The carbon concentration in the silicon may be between about 1 atomic percent and about 50 atomic percent. Such compositions may be achieved by depositing the layer from a gas mixture of methane in silane at a volumetric ratio from about 0 to about 0.5, such as between about 0.20 and about 0.35, for example about 0.25, at steady-state conditions (i.e. in the absence of any ramping that would cause deviation from these ratios).

At 108, a second layer is deposited while maintaining the low crystallinity deposition condition of the processing environment. Thus, a first crystalline layer is formed as process conditions are ramped to the low crystallinity deposition condition, and then deposition continues for a time period at the low crystallinity deposition condition.

In some cases, as illustrated by operation 110, the first layer is deposited during ramping using a first dopant source, and a second dopant source is added to the gas mixture while depositing the second layer. The first dopant source may be an n-type or p-type source, and the second dopant source may be a carbon source, or vice versa. In one instance, the first layer is deposited from a silicon source and an n-type source or a p-type source, and then a carbon source is added to deposit the second layer. This results in development of a stable crystal structure in the first layer before the carbon is added to the second layer. In this way, the first layer acts as a seed layer for the second layer.

In some instances, multiple sublayers may be deposited by changing the composition of the gas mixture during the deposition. Microcrystalline morphology is preserved by continuously depositing from the seed layer, while layer properties can be modulated by depositing sublayers having different properties. For example, multiple sublayers having alternating refractive index values may be deposited by alternating the composition of the gas mixture. In the example featuring a carbon alloy, the flow of the carbon source may be alternately started and stopped to deposit a plurality of microcrystalline layers having alternating values of refractive index. Such layers may function as Bragg reflectors at desired locations in a solar cell device.

In some embodiments, an n-type layer and a p-type layer may be formed using processes similar to that described above. For example, in one case an n-type layer may be formed by disposing a substrate in a process chamber, establishing a first flow condition comprising a flow rate of hydrogen, a first flow rate of a silicon source according to the ratios and flow rates described above, and a first flow rate of an n-type dopant source, and then ramping the flow conditions to a second flow condition by ramping the silicon source to a second flow rate of the silicon source higher than the first flow rate of the silicon source, and optionally ramping the n-type dopant source from the first flow rate of the n-type dopant source to a second flow rate of the n-type dopant source while ramping the silicon source. The first flow condition represents a high crystallinity deposition condition, and the second flow condition represents a low crystallinity deposition condition, as described above. Deposition of the n-type layer proceeds at the first flow condition, during ramping to the second flow condition, and at the second flow condition.

A p-type layer may also be formed by a similar process of establishing a third flow condition comprising a flow rate of hydrogen, a third flow rate of the silicon source, and a first flow rate of a p-type dopant source, and ramping the flow condition to a fourth flow condition by ramping the silicon source to a fourth flow rate, which may be higher than the third flow rate, as described above, and optionally ramping the p-type dopant source to a second flow rate of the p-type dopant source while ramping the silicon source. It should be noted that ramping of either the p-type dopant source or the n-type dopant source may take place concurrently with ramping the silicon source or before or after ramping the silicon source. Carbon may be added to each of the n-type and p-type layers, as described above, by introducing a carbon source during deposition of each layer.

In one particular embodiment, a substrate measuring 72 cm×60 cm (area 4,320 cm²) is disposed on a substrate support in a plasma chamber. A gas mixture comprising about 7 sccm silane, 15 sccm phosphine, and 30,000 sccm hydrogen is provided to the chamber at a pressure of about 2 Torr. The substrate is maintained at a temperature of about 200° C.

A capacitatively coupled plasma is formed from the gas mixture by coupling RF power at a frequency of 13.56 MHz and a power level of about 1 kW to start deposition. Deposition at these conditions is maintained for about 10 seconds to create a thin microcrystalline seed layer on the substrate.

The silane flow rate is ramped to about 75 sccm. The phosphine flow rate is ramped to about 150 sccm. The chamber pressure is ramped to about 10 Torr. The RF power level is ramped to about 2.5 kW. The hydrogen flow rate is held constant. The conditions are all ramped concurrently over a duration of about 60 seconds while deposition continues. After all conditions reach their end points, deposition is continued for about 10 seconds to stabilize the chamber.

Methane flow is established into the gas mixture at a rate of about 25 sccm to begin deposition of a phosphorus-doped microcrystalline silicon/carbon alloy layer. Deposition with carbon is maintained for a duration of about 60 seconds, after which carbon flow is stopped while deposition is maintained for about another 60 seconds.

As described above, further iterations of starting and stopping the carbon flow will result in multiple sublayers having different refractive indices, which will produce a Bragg reflector if reflectivity is needed. Also, as described above, such conditions may be used, substituting a p-type dopant source such as borane or diborane, to deposit a boron-doped microcrystalline silicon/carbon alloy layer.

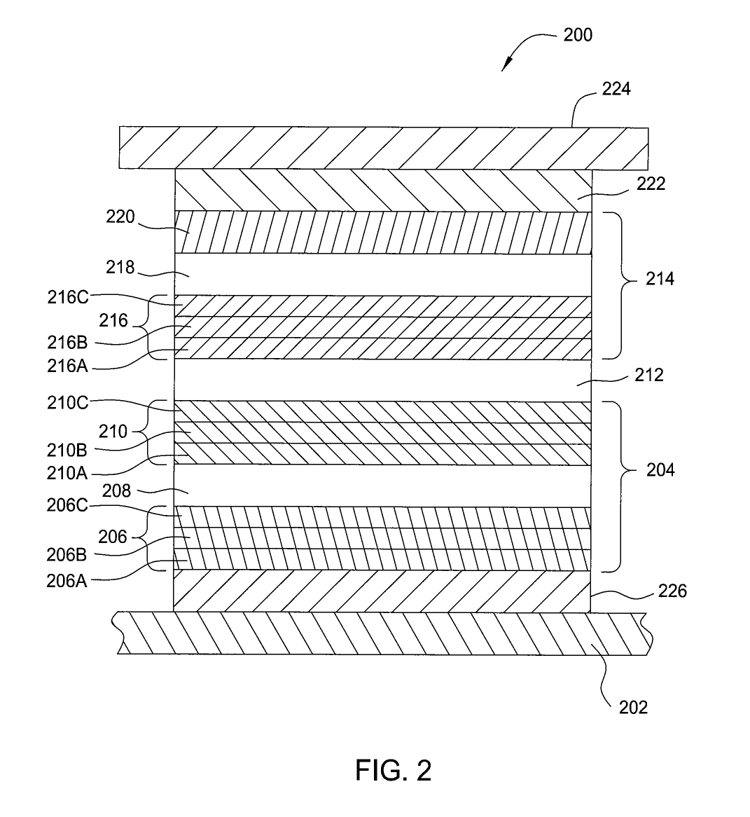

FIG. 2 is a schematic stack diagram of a device 200 according to another embodiment. The device 200 is a tandem junction solar cell having certain layers formed according to methods similar to those described above in connection with FIG. 1. Although the device 200 of Figure is a tandem junction solar cell, the layers described above in connection with FIG. 1 may be incorporated into a single junction solar cell as well.

The device 200 has a first structural substrate 202 and a second structural substrate 224, each of which is generally similar to the structural substrates described above. One of the first or second structural substrates 202 and 224 will generally be substantially transparent to admit light into the active layers of the device 200, and the other structural substrate will generally be reflective, and will generally have protective properties, such as moisture and oxygen barrier properties. A first conductor layer 226, generally similar to the conductor layers described above in connection with FIG. 1, is formed on the structural substrate 202. A first photovoltaic junction 204 is formed on the structural substrate 202. For the tandem junction device 200 of FIG. 2, a second photovoltaic junction 214 is formed over the first photovoltaic junction 204, with one or more optional buffer layers 212 disposed between the first and second photovoltaic junctions 204 and 214. For a single junction device, the second photovoltaic junction 214 would be omitted. A second conductor layer 222, also generally similar to those described above, is formed over the second photovoltaic junction 214. The first and second conductor layers 226 and 222 may be essentially the same, or they may be different if desired. One of the first and the second conductor 226 and 222 may have a reflective component such as a metal layer or dielectric mirror incorporated therein to enhance light capture.

Each of the photovoltaic junctions 204 and 214 separately comprises a p-type doped semiconductor layer, an intrinsic semiconductor layer, and an n-type doped semiconductor layer. The first photovoltaic junction 204 comprises a first microcrystalline n-type doped semiconductor layer 206, a first intrinsic semiconductor layer 208 that may be microcrystalline, amorphous, or a plurality of microcrystalline and amorphous layers, and a first microcrystalline p-type doped semiconductor layer 210. The second photovoltaic junction 214 comprises a second microcrystalline n-type doped semiconductor layer 216, a second intrinsic semiconductor layer 218, and a second p-type doped semiconductor layer 220.

Each of the intrinsic semiconductor layers 208 and 218 may be amorphous or microcrystalline, or some combination thereof. It is common to have at least one layer of amorphous intrinsic semiconductor material in the cell to absorb shorter wavelengths of light more efficiently.

The first microcrystalline n-type doped semiconductor layer 206 generally comprises a plurality of sublayers. In the embodiment of FIG. 2, three sublayers, 206A, 206B, and 206C, are shown, but more than three sublayers may be used. The first sublayer 206A is a microcrystalline semiconductor layer having an n-type dopant. The second sublayer 206B, which may contact the first sublayer 206A, is a microcrystalline semiconductor layer having an n-type dopant and a bandgap-enhancing dopant such as carbon. The third sublayer 206 C, which may contact the second sublayer 206B, is a microcrystalline semiconductor layer having an n-type dopant similar to the first sublayer 206A. The broader bandgap of the second sublayer 206B enhances the transmission of wavelengths of light through the layer, reducing absorption losses. The three sublayers may be formed using a process similar to that described in connection with FIG. 1. More than three sublayers may be formed by alternately depositing a layer having carbon and a carbon-free layer. The carbon-containing layers increase the overall bandgap of the first microcrystalline n-type doped semiconductor layer 206, reducing absorption of light, and the multiple layers of different refractive index reflect light back into the solar cell for improved light confinement.

The first microcrystalline n-type doped semiconductor layer 206 generally has a thickness between about 10 nm and about 200 nm, such as between about 50 nm and about 150 nm, for example about 100 nm. Depending on the number of sublayers and the overall thickness of the layer 206, each sublayer may have a thickness between about 10 nm and about 100 nm, such as between about 15 nm and about 50 nm, for example about 30 nm.

The second sublayer 206B may have up to about 50 atomic percent carbon, such as between about 1 atomic percent and about 15 atomic percent, or between about 5 atomic percent and about 10 atomic percent, for example about 6 atomic percent carbon. The addition of carbon to the second sublayer 206B increases the bandgap over microcrystalline silicon by between about 0.01 eV and about 0.20 eV, such as between about 0.05 eV and about 0.15 eV, for example about 0.10 eV. Refractive index is reduced by between about 0.2 and about 1.5, such as between about 0.5 and 1.2, for example about 0.7. Microcrystalline silicon/carbon alloys may have refractive index as low as about 2.3. The difference in refractive index between the sublayers reflects light at the interfaces between the layers to enhance light confinement in the solar cell.

The first microcrystalline p-type doped semiconductor layer 210 may comprise a plurality of sublayers, similar to the first microcrystalline n-type doped semiconductor layer. In the embodiment of FIG. 2, the first microcrystalline p-type doped semiconductor layer 210 has three sublayers 210A, 210B, and 210C. Similar to the first microcrystalline n-type doped semiconductor layer 206, the first and third sublayers 210A and 210C are free of carbon, while the second sublayer 210B is an alloy of silicon and carbon. The carbon reduces light absorption of the first microcrystalline p-type doped semiconductor layer 210 and reflects light back through absorber layers of the solar cell.

The second microcrystalline n-type doped semiconductor layer 216 may also comprise a plurality of sublayers, for example three sublayers 216A, 216B, and 216C, as shown in FIG. 2, and may be similar in many respects to the first microcrystalline n-type doped semiconductor layer 206. The carbon content of the layer 216 may be the same as for the layers 206 and 210, if desired, or the carbon content may vary to achieve incrementally different absorption properties. In general, the second microcrystalline n-type doped semiconductor layer will be formed by a process similar to that described in connection with FIG. 1 above.

The second p-type doped semiconductor layer 220 may be microcrystalline or amorphous depending on the optical properties desired. The second p-type doped semiconductor layer 220 may also have a plurality of sublayers, some of which may be alloys with carbon. If the second p-type doped semiconductor layer 220 is the nearest active layer to the light source, it may be advantageous to use a microcrystalline morphology with carbon to minimize absorption and reflectivity of light prior to the light reaching the first absorber layer. In many embodiments, one or more amorphous semiconductor layers are included as active layers to absorb wavelengths of light not readily absorbed by microcrystalline semiconductor layers.

Table 1 contains properties of three exemplary doped microcrystalline silicon carbon alloy layers made using the methods described herein. Each of the layers was formed to a thickness of about 50 nm and each includes a sublayer of doped silicon-carbon alloy between two sublayers of doped silicon. The overall carbon content of the layers was between about 0.5 atomic percent and about 6 atomic percent. The carbon content of the silicon-carbon alloy sublayers was between about 1 atomic percent and about 15 atomic percent.

TABLE 1
Exemplary Doped Microcrystalline Silicon Layer Properties

| Layer Type | N | P | N |
|---|---|---|---|
| Crystal Fraction (vol %) | 33.5 | 29.6 | 39.1 |
| Conductivity (S/cm) | 0.12 | 0.03 | 2.57 |
| E₀₄ Bandgap (eV) | 2.08 | 2.06 | 2.08 |
| 633 nm Absorption (%) | 0.03 | 0.02 | 0.03 |
| 633 nm Refractive Index | 3.56 | 3.52 | 3.56 |

While the foregoing is directed to embodiments of the invention, other and further embodiments of the invention may be devised without departing from the basic scope thereof.

What is claimed is:

1. A method of forming a thin-film solar cell, comprising:
positioning a substrate in a processing chamber;
exposing the substrate to a processing environment at a high crystallinity deposition condition in the processing chamber;
ramping the processing environment to a low crystallinity deposition condition;
depositing a first doped semiconductor layer on the substrate while ramping the processing environment; and
depositing a second doped semiconductor layer on the substrate while maintaining the low crystallinity deposition condition.

2. The method of claim 1, wherein the high crystallinity deposition condition comprises a first ratio of a volumetric flow rate of hydrogen to a first volumetric flow rate of a silicon source, and the low crystallinity deposition condition comprises a second ratio of the volumetric flow rate of hydrogen to a second volumetric flow rate of the silicon source, wherein the second ratio is lower than the first ratio.

3. The method of claim 2, wherein the first ratio is between about 200:1 and about 1,000:1, and the second ratio is between about 100:1 and about 700:1.

4. The method of claim 2, wherein the high crystallinity deposition condition further comprises a first plasma power level, and the low crystallinity deposition condition further comprises a second plasma power level, and the second plasma power level is higher than the first plasma power level.

5. The method of claim 2, wherein the high crystallinity deposition condition further comprises a first flow rate of a first dopant source, and the low crystallinity deposition condition further comprises a second flow rate of the first dopant source and a flow rate of a second dopant source.

6. The method of claim 5, wherein the first dopant source comprises phosphorous and the second dopant source comprises carbon.

7. The method of claim 2, wherein ramping the processing environment comprises ramping the volumetric flow rate of the silicon source from a first value to a second value, the first value being between about 1% and about 50% of the second value, while the flow rate of the hydrogen source is substantially constant.

8. The method of claim 1, wherein ramping the processing environment to a low crystallinity deposition condition comprises changing more than one process parameter concurrently.

9. A method of forming a solar cell, comprising:
forming a first photojunction layer adjacent to a first conductor layer on a substrate, the first photojunction layer comprising a first n-type doped semiconductor layer, a first intrinsic semiconductor layer, and a first p-type doped semiconductor layer, wherein the first n-type doped semiconductor layer is formed by a process, comprising:
exposing the substrate to a first gas mixture comprising a silicon containing gas at a first flow rate;
ramping the flow rate of the silicon containing gas to a second flow rate; and
depositing the first n-type doped semiconductor layer while ramping the flow rate of the silicon containing gas from the first flow rate to the second flow rate.

10. The method of claim 9, wherein the first p-type doped semiconductor layer is formed by a process, comprising:
exposing the substrate to a second gas mixture comprising the silicon containing gas at a third flow rate;
ramping the flow rate of the silicon containing gas to a fourth flow rate; and
depositing the first p-type doped semiconductor layer while ramping the flow rate of the silicon containing gas from the third flow rate to the fourth flow rate.

11. The method of claim 9, wherein the process of forming the first n-type doped semiconductor layer or the first p-type doped semiconductor layer further comprises adding a carbon source to the first gas mixture to deposit a carbon containing material on the substrate after ramping the silicon containing gas to the second flow rate.

12. A solar cell device, comprising:
a first microcrystalline doped semiconductor layer in contact with a first microcrystalline doped semiconductor alloy layer.

13. The solar cell device of claim 12, wherein the first microcrystalline doped semiconductor alloy layer comprises a semiconductor, a dopant, and an alloy material comprising carbon.

14. The solar cell device of claim 12, wherein the first microcrystalline doped semiconductor alloy layer comprises silicon, carbon, and an n-type or p-type dopant.

15. The solar cell device of claim 12, further comprising a second microcrystalline doped semiconductor layer in contact with a second microcrystalline doped semiconductor alloy layer.

16. The solar cell device of claim 15, wherein the first microcrystalline doped semiconductor layer and the second microcrystalline doped semiconductor layer are separated by an intrinsic semiconductor layer.

17. The method of claim 15, wherein the first and second microcrystalline doped semiconductor alloy layers each comprise silicon, carbon, and an n-type or p-type dopant.

18. The method of claim 17, wherein the first and second microcrystalline doped semiconductor layers and the first and second microcrystalline doped semiconductor alloy layers together define a photoelectric junction of the solar cell device.

19. The method of claim 17, wherein the first and second microcrystalline doped semiconductor alloy layers each comprise silicon, carbon at a concentration up to about 50 atomic percent, and an n-type or p-type dopant.
